(19) United States
(12) Patent Application Publication
(10) Pub. No.: US 2013/0134383 A1
(43) Pub. Date: May 30, 2013

(54) NON-VOLATILE MEMORY DEVICE AND METHOD OF MANUFACTURING THE SAME

(71) Applicant: SK hynix Inc., Gyeonggi-do (KR)

(72) Inventors: Eung Rim HWANG, Gyeonggi-do (KR); Hyo Seob YOON, Gyeonggi-do (KR)

(73) Assignee: SK HYNIX INC., Gyeonggi-do (KR)

(21) Appl. No.: 13/689,366

(22) Filed: Nov. 29, 2012

(30) Foreign Application Priority Data
Nov. 29, 2011 (KR) 10-2011-0126354

(51) Int. Cl. H01L 45/00; H01L 27/24

(52) U.S. Cl. CPC H01L 45/16; H01L 27/2481
USPC 257/5; 438/382

(57) ABSTRACT

A non-volatile memory device and a method of manufacturing the same are provided. A first portion stack having a first circuit element including at least one layer selected from at least one diode layer, at least one variable resistive layer, and interconnection layer is formed on a first substrate. A second portion stack having a second circuit element including at least the other layer selected from the at least one diode layer, the at least variable resistive layer, and the at least interconnection layer is formed on a second substrate. The first circuit element and the second circuit element are bonded together and the second substrate is removed.

### CROSS-REFERENCES TO RELATED APPLICATION

The present application claims priority under 35 U.S.C. 119(a) to Korean application number 10-2011-0126354, filed on 2011-11-29, in the Korean Patent Office, which is incorporated by reference in its entirety.

### BACKGROUND

1. Technical Field

The examples of the present invention relate to semiconductor technology, and more particularly, to a non-volatile memory device and a method of fabricating the same.

2. Related Art

In recent years, with an increase in demand for portable digital application devices such as digital cameras, MP3 players, personal digital assistants (PDAs), and mobile phones, the non-volatile memory market is rapidly expanding. As flash memory devices, which are programmable non-volatile memory devices, reach the limit of scaling, non-volatile memory devices, such as phase-change random access memory (PcRAM) devices or resistive random access memory (ReRAM) devices, which use a variable resistor having a reversibly changeable resistance value, have received attention as alternative non-volatile memory devices to the flash memory devices.

In general, a unit cell of the non-volatile memory device may include the variable resistor and a switching element electrically connected to the variable resistor. The switching element may be a MOS transistor. Since a current of at least several mA is necessary to change a state of the variable resistor, there is a limit to a size that the MOS transistor can be reduced when scaling of the device. Thus, in recent years, there is a trend to replace the MOS transistor with a vertical diode, as a switching element, in order to reduce size and increase the degree of integration.

By using the vertical diode, the variable resistors, and the diodes connected to the variable resisters in series, are disposed between lower interconnections and upper interconnections which have stripe shapes and cross each other, so that a non-volatile memory device may be implemented to be a cross point structure having an integration degree of 4F2. In such a structure, the variable resistor and diode are necessary to be formed in a consecutively stacked structure in a direction perpendicular to a principal surface of a substrate.

In a general silicon-based semiconductor fabrication process, a process of forming a diode is performed at a temperature above about 550° C. In contrast to the diode, a variable resistor layer is desirable to be formed below a temperature of about 400° C., since the variable resistor layer is highly likely to be degraded above a temperature of about 400° C. Thus, in general, the diode is generally formed first and then the variable resistor is formed. However, this sequence of forming the diode and variable resistor may need to be reversed for implementing multi-bits memory for higher density or capacity or in terms of a driving scheme of the non-volatile memory device.

In addition, to enhance a rectifying characteristic of a diode, an additional impurity region may be formed in an end portion of the diode or an intrinsic semiconductor layer may be inserted between a PN junction. A height of the vertical diode may be increased to enhance an ON current in the vertical diode, or to prevent a leakage current by a parasitic transistor that is formed between the vertical diodes adjacent to each other.

Conventionally, a vertical diode has a height of about 3000 Å or more. When taking into consideration the variable resistor connected to the vertical diode consideration, a unit memory cell has a high aspect ratio. When manufacturing a conventional unit memory cell having such a high aspect ratio a diode layer, a variable resistive layer, and an electrode layer are sequentially stacked on a substrate, a suitable mask pattern is formed on a resultant structure, and the electrode layer, the variable resistive layer, and the diode layer are continuously etched to form the unit memory cell. However, the approach may cause a fabrication failure due to a phenomenon in which some of the unit memory cells having a high aspect ratio lean during a patterning process.

### SUMMARY

One or more exemplary embodiments are provided to a method of manufacturing a memory cell which is capable of variously modifying a design for the memory device and easily performing manufacture process.

One or more exemplary embodiments are provided to a nonvolatile memory device having the above-described advantages.

According to one aspect of an exemplary embodiment, there is a provided a method of manufacturing a memory cell which includes at least one diode layer, at least one variable resistive layer and at least one interconnection layer. The at least one diode layer and the at least one variable resistive layer are coupled with each other and arranged perpendicular to a surface of a substrate. The at least one interconnection layer is electrically connected with one end of the coupled at least one diode layer and at least one variable resistive layer. The method may comprise; forming, on the substrate, a first portion stack having a first circuit element including at least one layer selected from the at least one diode layer, the at least one variable resistive layer, and the interconnection layer; forming, on a handle substrate, a second portion stack having a second circuit element including at least the other layer selected from the at least diode layer, the at least variable resistive layer, and the at least interconnection layer; joining the second portion stack on the handle substrate with the first portion stack on the substrate to electrically connect the first circuit element and the second circuit element; and removing the handle substrate from the second portion stack.

In some embodiments, the joining the second portion stack with the first portion stack may comprise forming a first bonding layer between the first circuit element and the second circuit element. The first bonding layer may include a metal suicide layer, a eutectic alloy layer, or a combination thereof. In another embodiment, the method may further comprise forming a first interlayer insulating layer over the first circuit element and a second interlayer insulating layer over the second circuit element. The joining the second portion stack with the first portion stack may further comprise forming a second bonding layer between the first interlayer insulating layer and the second interlayer insulating layer. The second bonding layer may include a reaction layer formed by a siloxane network, a Vander Waals bonding layer, or a combination thereof.

The method may further comprise forming an insertion layer partially or entirely on at least one of an upper surface of the first portion stack and an upper surface of the second portion stack. The insertion layer may comprise an intermediate electrode layer, a diffusion barrier layer, an ohmic contact layer, and a bonding material layer or a stacking structure including at least two or more of the intermediate electrode layer, the diffusion barrier layer, the ohmic contact layer, or the bonding material layer. In some embodiments, the at least diode layer may include a silicon-based semiconductor material and the insertion layer may include a silicidable metal material.

The at least one layer and the at least one variable resistive layers may be arranged to have a pillar structure. The at least one variable resistive layer may include a phase-change material, a variable resistive material, a programmable metallization cell (PMC) material, or a combination thereof. In some embodiments, the at least one diode layer may include a PN junction diode, a p-type semiconductor-intrinsic semiconductor-n-type semiconductor (PIN) diode, a Shottky barrier diode, and a Zener diode or a combination thereof.

The at least one interconnection layer may be formed by a damascene process or a dual damascene process. The at least interconnection layer having a damascene or dual damascene structure may include a noble metal, a noble metal alloy, copper, or a copper alloy. In some embodiments, the method may further include forming a diffusion barrier layer on any one of the interconnection layers.

In some embodiments, a plurality of first memory cells are formed in the first portion stack, each memory cell including a first diode layers, a first variable layer, and a first interconnection layer on the substrate. A plurality of second memory cells are formed in the second portion stack, each second memory cell including a second diode layer, a second variable resistive layer, and a second interconnection layer on the handle substrate. In this case, the first interconnection layer or the second interconnection layer is a common interconnection layer for both the first memory cell and the second memory cell.

According to another aspect of an exemplary embodiment, there is a provided a method of manufacturing a nonvolatile memory device. The method may include: forming, perpendicular to a surface of a substrate, a first portion stack including a plurality of first memory cells, where each first memory cell of the plurality of first memory cells includes a first diode layer, a first variable resistive layer, and a first interconnection layer; forming, perpendicular to a surface of a handle substrate, a second portion stack including a plurality of second memory cells, where each second memory cell, of the plurality of second memory cells, includes a second diode layer, a second variable resistive layer, and a second interconnection layer; bonding the second portion stack with the first stack portion; and removing the handle substrate from the second portion stack.

In some embodiments, the first interconnection layer or the second interconnection layer may be a common interconnection layer for both the plurality of first memory cells and the plurality of second memory cells.

According to another aspect of an exemplary embodiment, there is provided a memory device having a plurality of memory cells. Each memory cell, of the plurality of memory cells, may include at least one diode layer, at least one variable resistive layer and at least one interconnection layer, where the at least one diode layer and the at least one variable resistive layer are coupled with each other and arranged perpendicular to a surface of a substrate, and the at least one interconnection layer may be electrically connected with one end of the coupled at least one diode layer and at least one variable resistive layer. The memory device may comprise; a first portion stack having a first circuit element including at least one layer selected from the at least one diode layer, the at least one variable resistive layer, and the interconnection layer; a second portion stack having a second circuit element including at least the other layer selected from the diode layers, the variable resistive layers, and the interconnection layer; and a bonding layer formed between the first portion stack and the second portion stack.

The bonding layer may include a metal silicide layer, a eutectic alloy layer, or a combination thereof. The at least one diode layer and the at least one variable resistive layer may be arranged to have a pillar structure. The at least one variable resistive layers may include a phase-change material, a variable resistive material, a PMC material, or a combination thereof. The at least one diode layer may include a PN junction diode, a PIN diode, a Shottky barrier diode, a Zener diode or a combination thereof.

In some embodiments, at least any one of the first and second interconnection layers may have a damascene structure or a dual damascene structure. The interconnection layer formed by the damascene or dual damascene process may include a noble metal, a noble metal alloy, copper, or a copper alloy.

In another embodiment, the memory device may further include a first interlayer insulating layer which passivates a first circuit element; a second interlayer insulating layer which passivates a second circuit element; and a second bonding layer formed between the first interlayer insulating layer and the second interlayer insulating layer. The second bonding layer may include a reaction layer formed by a siloxane network, a Vander Waals bonding layer, or a combination thereof.

In some embodiments, the plurality of memory cells may include a first portion stack including a plurality of first memory cells, where each first memory cell of the plurality of first memory cells includes a first diode layer, a first variable resistive layer, and a first interconnection layer; a second portion stack including a plurality of second memory cells, where each second memory cell, of the plurality of second memory cells, includes a second diode layer, a second variable resistive layer, and a second interconnection layer; and, a bonding layer formed between the first portion stack and the second portion stack.

In some embodiments, any one of the first and second intersection layers may be shared between the plurality of first memory cells and the plurality of second memory cells. The bonding layer configured to bond the first stack portion with the second portion stack may be formed on the one interconnection layer. The bonding layer may include a metal silicide layer, a eutectic alloy layer, or a combination thereof.

In some embodiments, the memory device may further a first interlayer insulating layer over the first circuit element and a second interlayer insulating layer over the second circuit element or more diode layers. In this case, the boding layer may be formed between the first interlayer insulating layer and the second interlayer insulating layer. The bonding layer may include a reaction layer formed by a siloxane network, a Vander Waals bonding layer or a combination thereof.

According to the exemplary embodiment, an array of a plurality of memory cells, which have circuit elements, for example, variable resistive layer and diode layer arranged in a perpendicular direction to a substrate, may be divided into two or more portion stacks and separately processed on the respective portion stacks. The array of a plurality of memory cells can be obtained by bonding the respective portion stacks to one another. Thus, the diode layer and the variable resistive layer may be formed through separate processes, and a thermal burden for forming the diode layer is independent of a process of forming the variable resistive layer. As a result, a film quality of the diode layer and the variable resistive layer may be improved independently irrespective of the sequence of the formation of the diode layer and variable resistive layer.

These and other features, aspects, and embodiments are described below.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1a to 1c illustrate circuit diagrams of exemplary unit memory cells;

FIGS. 2a to 2c illustrate an exemplary process for manufacturing an exemplary non-volatile memory device;

FIGS. 3a to 3c illustrate an exemplary process for manufacturing a non-volatile memory device;

FIGS. 4a to 4d illustrate an exemplary process for manufacturing a non-volatile memory device;

FIGS. 5a to 5c illustrate an exemplary process for manufacturing a non-volatile memory device;

FIG. 6 illustrates an electronic system including an exemplary non-volatile memory device; and

FIG. 7 illustrates a memory card including an exemplary non-volatile memory device.

### DETAILED DESCRIPTION

Hereinafter, exemplary embodiments will be described in greater detail with reference to the accompanying drawings.

The present invention may, however, be embodied in many different forms and should not be construed as being limited to the embodiments set forth herein; rather, these embodiments are provided so that this disclosure will be thorough and complete, and will fully convey the concept of the invention to those skilled in the art.

Like reference numerals in the drawings denote like elements. The term “and/or” used herein includes any one of listed items or a combination of two or more thereof.

The terminology used herein is for the purpose of describing particular embodiments only and is not intended to be limiting of the present invention. As used herein, the singular forms n″ and “the” are intended to include the plural forms as well, unless the context clearly indicates otherwise. It will be further understood that the terms “comprises” and/or “comprising,” when used in this specification, specify the presence of stated features, integers, steps, operations, elements, components and/or the group thereof, but do not preclude the presence or addition of one or more other features, integers, steps, operations, elements, components, and/or groups thereof.

It is also understood that when a layer is referred to as being “on” another layer or substrate, it can be directly on the other or substrate or intervening layers or layers formed in the intervening layers may also be present. It will be clearly understood by those skilled in the art that a structure or shape “adjacent to” another shape may have a portion overlapping the other shape or a portion below the other shape.

Spatially relative terms, such as “below”, “above”, “upper”, “lower” “horizontal”, or “vertical”, may be used herein for ease of description to describe one element, layer, or region's relationship to another element(s), layer(s), or region(s) as illustrated in the figures. It will be understood that the spatially relative terms are intended to encompass different orientations of the device in use or operation in addition to the orientation depicted in the figures.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result for example, from manufacturing. In the drawings, lengths and sizes of layers and regions may be exaggerated for clarity.

Herein, a term “substrate” is collectively referred to as a base structure such as silicon, silicon-on-insulator (SOI), or silicon-on-sapphire (SOS), a semiconductor layer formed on another base structure other than semiconductor, doped or undoped semiconductor layer, or a modified semiconductor layer. Terms “base structure” and “semiconductor” is not limited to a silicon-based material, but collectively referred to as carbon, polymer, silicon-germanium (SiGe), Ge, a group III-V semiconductor material such as a gallium-arsenide (GaAs)-based compound material, a group II-VI semiconductor material, or a mixed semiconductor material.

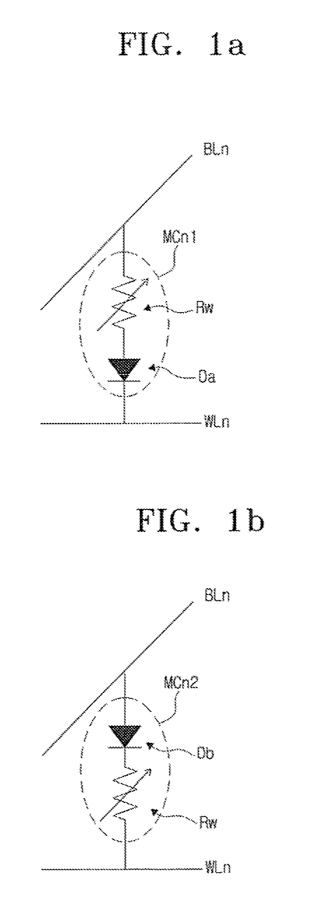

FIGS. 1a to 1c illustrate circuit diagrams of exemplary unit memory cells MCn1, MCn2, and MCn3 that may be associated with a non-volatile memory device.

Referring to FIG. 1a, an exemplary non-volatile memory device may include a first interconnection WLn and a second interconnection BLn. The first interconnection WLn and the second interconnection BLn may include a plurality of conductive lines arranged parallel to one another in different planes. The first interconnection WLn and the second interconnection BLn are arranged to cross each other in an array. The array of the interconnections WLn and BLn may be a two dimensional array or a three dimensional. In an exemplary embodiment, the first interconnection WLn may be a word line and the second interconnection BLn may be a bit line. However, the terms, i.e., word line and e bit line may be interchangeably used herein and the present invention is not limited by the terms.

The unit memory cell MCn1 is electrically connected to the first and second interconnections WLn and BLn at an intersection thereof. The unit memory cell MCn may include at least one of a serial connection circuit of variable resistor Rw and diode Da. As shown in FIG. 1a, the variable resistor Rw may include a single resistive memory device. In an alternative embodiment a plurality of resistive memory devices may be connected in series or in parallel, so that a total programming resistance level R is provided with various values, for example, R1<R2<R3<R4. Thus, the non-volatile memory device may store multi-bit information.

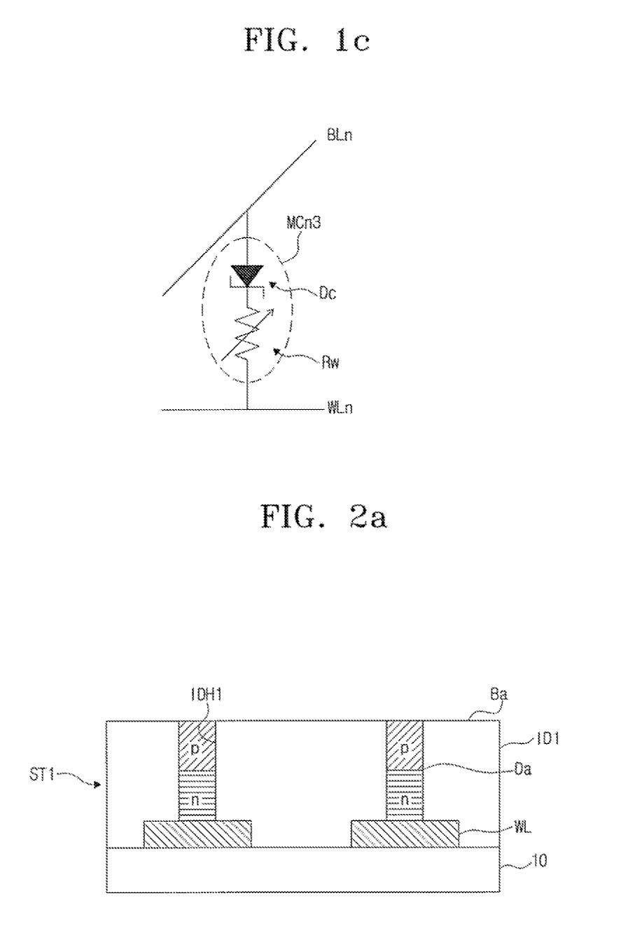

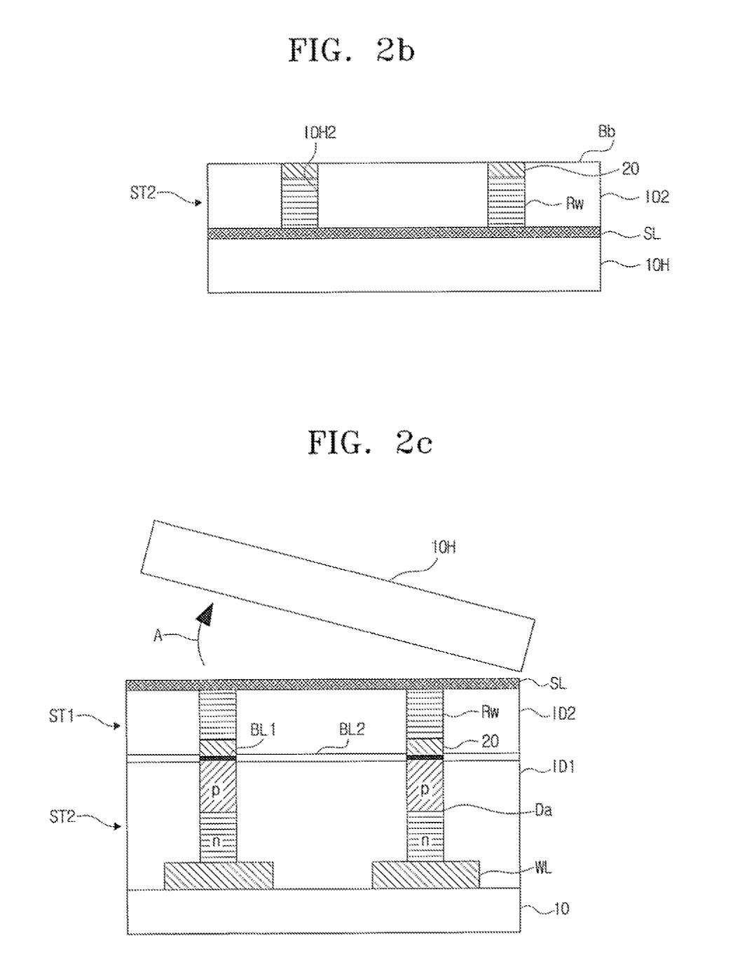

The variable resistor Rw may include a material for providing a non-volatile solid-state memory cell, for example, a phase-change material, a variable resistive material, a PMC material, or a combination thereof. The materials for the variable resistor Rw will be described in detail later with reference to FIG. 2b.

In an exemplary embodiment, the diode Da may include a PN junction diode. In the diode Da, a portion connected to the word line WLn may be a cathode and a portion connected to the variable resistor Rw may be an anode. In an exemplary embodiment, a polarity of the diode Da may be reversed if a unit memory cell is selected based on a potential difference between the word line WLn and the bit line BLn.

With respect to an operation of the diode Da, when a unit memory cell MCn1 is in a non-selected state, the diode Da is in a reverse-bias state together with diodes (not shown) of other non-selected unit memory cells. For example, if a signal of a high level and a signal of a low level are applied to the first interconnection WLn and the second interconnection BLn, respectively, then the diode Da enters a reverse bias state. On the other hand, when the unit memory cell MCn1 is in a selection state, if a signal of a low level and a signal of a high level are applied to the first interconnection WLn and the second interconnection BLn, respectively, then the diode Da enters a forward bias state. At this time, a magnitude of an amount of current flowing in the selected unit memory cell may be detected to read out binary data.

The unit memory cell MCn1 may be programmed obtained by increasing the current flowing in the selected unit memory cell MCn1 and changing a resistance state of the variable resistor Rw.

Bit values “0” and “1” may be allocated according to a resistance state, as recording information. For example, the bit value “1” may be allocated to a low resistance state (in general, referred to as a set state) and the bit value “0” may be allocated to a high resistance (in general, referred to as a reset) so that information may be processed. In an alternative embodiment, the allocation of the bit values “0” and “1” may be reversed.

Referring to FIG. 1b, in an exemplary diode Db used in a cell selection may be a Schottky barrier diode. The Schottky barrier diode is a majority carrier device in which a minority carrier is minimally accumulated, unlike in the PN junction diode. Thus, the SCHOTTKY diode has an advantage of high speed access. Since a semiconductor junction structure is not necessary in the Schottky barrier diode, a configuration of a cell array and a fabrication process are simplified.

In addition, as shown in FIG. 1b, an exemplary unit memory cell MCn2 may be configured so that a variable resistor Rw is connected to the word line WLn and the diode Db is connected to the bit line BLn. The connection arrangement of the variable resistor Rw and the diode Db in the unit memory cell MCn2 is opposite to the arrangement the unit memory cell MCn1, as shown in FIG. 1a.

Referring to FIG. 1c, an exemplary diode Dc used in a cell selection may be a bidirectional diode. The bidirectional diode may have a first threshold voltage, when a forward bias is applied thereto, and a second threshold voltage when a reverse bias is applied thereto. For example, the bidirectional diode Dc may be a Zener diode. A breakdown voltage of the Zener diode may be the second threshold voltage of the bidirectional diode Dc. For example, the Zener diode may be an NPN Zener diode or a PNP Zener diode.

Although not shown, an exemplary non-volatile memory device may include other diodes having a rectifying characteristic. These diodes may be applied to the non-volatile memory device by replacing the diodes Da, Db, and Dc or may be used in combination with the diodes Da, Db, and Dc. Thus, the diodes are merely illustrative and the present invention is not limited to the above-described diodes. For example, a diode with a p-type layer-intrinsic semiconductor layer-metal layer (PIM) structure, or a diode with an n-type layer-intrinsic semiconductor layer-metal layer (NIM) structure, which has a rectifying characteristic, may be utilized together with the above-described diodes in the unit memory cell or replace the above-described diodes in the unit memory cell.

Thus, in the variable resistor and diode implementing the unit memory cell MCn1, MCn2, or MCn2, the connection arrangement, junction configuration may be understood to be variously modified depending on a desired operation characteristic and performance improvement of the memory cell. Hereinafter, a method of manufacturing a non-volatile memory device including the various diodes will be described.

FIGS. 2a to 2c illustrate an exemplary method of manufacturing a non-volatile memory device, including the unit memory cell shown in FIG. 1a. FIGS. 2a to 2c illustrate only a portion of a memory cell array area. Other circuit elements configured in a peripheral area adjacent to the memory cell array area, for example, high voltage transistors and low voltage transistors, and interconnections for electrical connection thereof may be implemented using known technologies.

Referring to FIG. 2a a first interconnection layer WL may be formed on a substrate 10. The first interconnection layer WL may include a metallic pattern layer including a metal, such as aluminum, copper, an alloy thereof, or conductive metal oxide, or a high concentration impurity layer including n-type or p-type impurity elements.

The metallic pattern layer for the first interconnection layer WL may be formed by forming a suitable metal layer on the substrate 10 and then etching the metal layer though a photolithography and etching processes, or through a damascene or dual damascene process. The high concentration impurity layer for the first interconnection layer WL may be formed by ion implanting an n-type or a p-type impurity into an active region of the memory cell array area of the substrate 10. The first interconnection layer WL may correspond to the word line WLn shown in FIG. 1a.

Next, a first interlayer insulating layer ID1 may be formed on the first interconnection layer WL. The first interlayer insulating layer ID1 may include silicon oxide or silicon nitride formed by, for example, a high density plasma (HDP) deposition method. Alternatively, the first interlayer insulating layer ID1 may include a layer to form a molecular bonding layer, such as a reaction layer, by network formation for a bonding process of the portion stacks ST1 and ST2, as will be described later. The molecular bonding layer may include a metastable insulating layer, such as silicon oxide-like layer or silicon nitride-like layer. In addition, the first interlayer insulating layer ID1 may be selected from materials that are bondable to a second interlayer insulating layer ID2 by Vander Waals force, as will be described later.

Subsequently, holes IDH1 for a diode layer Da may be defined in the first interlayer insulating layer ID1. Portions of a surface of the first interconnection layer WL may be exposed by the holes IDH1.

Next, a semiconductor layer for a diode may be filled in the holes IDH1. When the first interconnection layer WL is a high concentration impurity layer, the semiconductor layer for a diode may be formed on exposed portions of the high concentration impurity layer by a selective epitaxial growth (SEG) method or a solid-phase epitaxy (SPE) method. In an exemplary embodiment, when the first interconnection layer WL is a metallic pattern layer, the semiconductor layer for a diode may be formed by filling a polysilicon layer in the holes IDH1. Impurity regions P and N may be formed, by in situation implantation, in the semiconductor layer for providing a diode, while the semiconductor layer for the diode is deposited, or after the semiconductor layer for the diode is deposited. Then, an appropriate annealing process may be performed to form the diode layer Da.

Alternatively, before forming the first interlayer insulating layer ID1, the semiconductor layer including the impurity regions may be formed on the substrate 10 on which the first interconnection layer WL is formed. Next, the diode layer Da may be formed by forming a PN junction in the semiconductor layer through suitable heat treatment and patterning the semiconductor layer. Subsequently, the first interlayer insulating layer ID1 is formed to electrically isolate the diode layer Da. If necessary, the heat treatment for forming the PN junction may be performed after forming the first interlayer insulating layer ID1, however the present invention is not limited thereto.

By the above-described processes, a first portion stack ST1, including a first circuit element having the first interconnection layer WL and the diode layer Da stacked perpendicular to a surface of the substrate 10, may be provided. Although not shown, one and more additional layers, such as an ohmic contact layer, a metal silicide layer, or an impurity layer, may be formed between the first interconnection layer WL and the diode layer Da.

Referring to FIG. 2b, a second portion stack ST2, including a second circuit element that is to be in contact with a surface Ba of the first portion stack ST1 of the substrate 10, may be formed on a handle substrate 10H. The handle substrate 10H may be removed in a subsequent process. Any substrate may suffice as the handle substrate 10H, as long as conventional processes for fabricating a semiconductor device fabrication processes can be practicable on it. For example, the handle substrate 10H may be a dummy wafer. The handle substrate to be removed in the subsequent process film may be reused as a handle substrate or for any other purpose.

A separation layer SL may be provided on the handle substrate 10H to separate the second portion stack ST2 from the handle substrate 10H. Thus, the separation layer SL enables the handle substrate 10H to be easily removed. The separation layer SL may be a fragile layer in the handle substrate 10H to allow the handle substrate 10H to be easily removed.

If the handle substrate 10H is a silicon substrate, then the separation layer SL may include a buried layer, such as an implanted oxygen layer (SIMOX). However, the handle substrate 10H is merely illustrative and the present invention is not limited thereto. For example, the separation layer SL may include a silicon layer having hydrogen-implantation-induced layer splitting (Smart-Cut™) a cleave plane that is capable of a nanocleave process, or a high porosity that can be split by a water jet.

A variable resistive layer Rw is formed on the handle substrate 10H on which the separation layer SL is formed. The variable resistive layer Rw may include a phase-change material, a variable resistive material, a PMC material, or a combination thereof, to provide a non-volatile solid-state memory cell.

The phase-change material may include a material that can be reversibly changed from an amorphous phase to a crystalline phase, or vice versa, thereby having different resistance values. Typically, the phase-change material has a high resistance value when having the amorphous phase and a low resistance value when having the crystalline phase. For example, the phase-change material may include a chalcogenide compound such as a germanium-antimony-tellurium (GeSbTe)-based material. For example, the GeSbTe-based material may include GeSb₂Te₃, Ge₂Sb₂Te₅, GeSb₂Te₄, or a combination thereof. Alternatively, the phase-change material may include germanium-tellurium-arsenic (GeTeAs), germanium-tin-tellurium (GeSnTe), selenium-tin-tellurium (SeSnTe), gallium-selenium-tellurium (GaSeTe), germanium-tellurium-tin-gold (GeTeSnAu), selenium-antimony (SeSb₂), indium-selenium (InSe), germanium-tellurium (GeTe), bismuth-selenium-antimony (BiSeSb), palladium-tellurium-germanium-tin (PdTeGeSn), indium-selenium-titanium-cobalt (InSeTiCo), indium-antimony-tellurium (InSbTe, In₃SbTe₂), germanium-tellurium-antimony (GeTeSb₂, GeTe₃Sb), germanium-antimony-tellurium-palladium (GeSbTePd) or silver-indium-antimony-tellurium (AgInSbTe). However, these phase-change materials are merely illustrative and the present invention is not limited thereto. Moreover, the phase-change material, which may include any of the above described materials, may be doped with an impurity, for example, a nonmetallic element such as boron (B), carbon (C), nitrogen (N), or phosphorus (P).

In another exemplary embodiment, the variable resistive layer Rw may include a variable resistive material. The variable resistive material is a material that may be reversibly switched between a low resistance state and a high resistance state without phase change of the material by various switching mechanisms. In connection with the switching mechanism, many physical and theoretical models, including a conductive filament, an interfacial effect, the change in the oxidation state of the cations, or trap charge effect have been suggested. However, the switching mechanisms are still unclear although the switching behavior itself has been clearly observed. For example, the variable resistive material may include a Perovskite-based oxide, such as strontium titanium oxide (SrTiO₃), strontium zirconium oxide (SrZrO₃), or Nb:SrTiO₃, or a transition metal oxide, such as titanium oxide(TiOₓ) nickel oxide (NiO), tantalum oxide (TaOₓ), hafnium oxide (HfOₓ), aluminum oxide (AlOₓ), zirconium oxide (ZrOₓ), copper oxide (CuOₓ), niobium oxide (NbOₓ), gallium oxide (GaOₓ), gadolinium oxide (GdOₓ), manganese oxide (MnOₓ), or any combination of these materials, such as praseodymium calcium manganese oxide (PrCaMnO), or zinc oxide-nickel oxide(ZnONIOₓ). These perovskite-based oxides or transition metal oxides have a resistance value that varies in response to an electrical signal.

The variable resistive material may have unipolar or bipolar swithing characteristics. Thus, the variable resistive layer Rw may include a unipolar resistive material or a bipolar resistive material. Alternatively, the variable resistive layer Rw may include a stacked structure of a layer including the unipolar resistive material and a layer including the bipolar resistive material to be designed for implementing a multi-bit memory device.

An exemplary variable resistive layer Rw may include a PMC material. The PMC material may include two metal electrodes and an electrolyte material that is interposed between the two metal electrodes and includes super ion regions. One of the two metal electrodes includes an electrochemically active metal, for example, an oxidizable metal, such as silver (Ag), tellurium (Te), copper (Cu), tantalum (Ta) or titanium (Ti). The other metal electrode may include a relatively inert metal, such as tungsten (W), gold (Au), platinum (Pt), palladium (Pd) or rhodium (Rh). A resistance or a switching characteristic of the PMC material may occur through a physical relocation of the super ion regions in the electrolyte material. The electrolyte material having the super ion regions may include, for example, a base glass material, such as a germanium-selenium (GeSe) compound material. The GeSe compound material may be referred to as chalcogenide glass or a chalcogenide material. The GeSe compound material may include, for example, Ge₃Se₇, Ge₄Se₆ or Ge₂Se₃. In addition, any commonly known PMC material may be used. The materials for variable resistive layer Rw may have a single-layered structure or a plurality of stacked structures formed of multiple layers. The stacked structures may be combined with one another so that the stacked structures may be connected in series or in parallel between the interconnection layers (WLn and BLn of FIG. 1a).

The materials for the variable resister Rw described above are merely illustrative and the present invention is not limited to the above mentioned materials. For example, the variable resistive layer may include a well-known high polymer-based material or a polymer thin film containing suitable nanoscale metal particles dispersed in the polymer-based material. An exemplary variable resistive layer Rw may be formed on a separate substrate from the diode layer Da, so that a high temperature process may be performed on the diode layer Da, and a variable resistive layer may be formed using a low temperature process.

An insertion layer 20 may be formed on the variable resistive layer Rw. The insertion layer 20 may be an intermediate electrode layer interposed between the variable resistive layer Rw and the diode layer Da, as will be described later. The intermediate electrode layer may include a lower electrode layer of the variable resistive layer Rw, a diffusion barrier layer, or an ohmic contact layer, or may perform the combined functions thereof. For example, when the non-volatile memory device is a PcRAM, the insertion layer 20 may be a heater electrode. The second circuit elements, including the variable resistive layer Rw and insertion layer 20, of the second portion stack ST2 has a stacking arrangement opposite to the connection arrangement of the unit memory cell MCn1 of FIG. 1a.

When the insertion layer 20 is the intermediate electrode layer, the insertion layer 20 may include a conductive layer, such as metal layer, an alloy layer, metal oxynitide layer, metal nitride layer, a conductive carbon compound layer, or a semiconductor material layer. For example, the insertion layer 20 may include tungsten (W), titanium (Ti), tantalum (Ta), molybdenum (Mo), niobium (Nb), platinum (Pt), tungsten nitride (WN), titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium oxynitride (TON), titanium aluminum oxynitride (TiAlON), tungsten oxynitride (WON), iridium oxide (IrO₂), overdoped conductive polysilicon, or any combination thereof.

An exemplary insertion layer 20 may include a bonding material layer configured to bond the first portion stack ST1 to the second portion stack ST2, as will be described later. The bonding material layer may include a conductive layer that is subject to silicidation or metal alloying, for example by a eutectic reaction. However, these conductive layers are merely illustrative, and the bonding material may include a metastable metal having a metallic conductivity.

When the diode layer Da includes a silicon-based semiconductor material, the bonding material layer may include a metal material that is subject to silicidation with the diode layer Da. An exemplary metal material may include Ti, Ta, Pt, iridium (Ir), ruthenium (Ru) palladium (Pd), erbium (Er), yttrium (Y), W hafnium (Hf), vanadium (V), chromium (Cr), manganese (Mn), iron (Fe), zirconium (Zr), cobalt (Co), or nickel (Ni).

When a conductive layer that is subject to a eutectic reaction is utilized as the bonding material layer, a first bonding material layer may be formed on the diode layer Da of the first portion stack ST1 and a second bonding material layer may be formed on the variable resistive layer Rw of the second portion stack ST2. For example, the first bonding material layer may include a different material from that of the second bonding material layer, and each of the first bonding material layer and the second bonding materials may include gold (Au), silver (Ag), aluminum (Al), copper (Cu), silicon (Si), Mo, tin (Sb), lead (Pb), gallium (Ga), bismuth (Bi), indium (In), or Zn.

The first bonding material layer may be bonded to the second bonding material layer in a subsequent bonding process between the first portion stack ST1 and the second portion stack (ST2), thereby forming a eutectic reaction layer. For example, the eutectic reaction layer may include a binary alloy layer or a ternary alloy layer such as Au—Sn, Sn—Zn, Bi—In—Sn, or Bi—In—Pb. The eutectic reaction layer may be obtained through rapid thermal annealing at a temperature of about 400° C. or less or low temperature bonding by laser.

An exemplary insertion layer 20 may have a stacked structure including at least two or more layers, such as an intermediate electrode layer, the diffusion barrier layer, the ohmic contact layer, or the bonding material layer described above. For example, the insertion layer 20 may have a two-layered structure including the intermediate electrode layer and the bonding material layer.

These layers may be stacked on the handle substrate 10H and then continuously patterned to form the second circuit elements. A second interlayer insulating layer ID2 may be formed on the handle substrate 10H to electrically insulate the second circuit elements. An exemplary second interlayer insulating layer ID2 may include the same material as the first interlayer insulating layer ID1. For example, the second interlayer insulating layer ID2 may include silicon oxide or silicon nitride formed by a HDP method. An exemplary second interlayer insulating layer ID2 may include a layer that easily forms a molecular bonding layer with the first interlayer insulating layer ID1 for a bonding process. The molecular bonding layer may including reaction layer by a network formation between the first interlayer insulating layer ID1 and the second interlayer insulating layer ID2. The second interlayer insulating layer ID2 may include a metastable insulating layer, such as silicon oxide-like material or silicon nitride-like material. Alternatively, the second interlayer insulating layer ID2 may be bonded to the first interlayer insulating layer ID1 through Vander Waals bonding.

An exemplary second interlayer insulating layer ID2 may be formed before the second circuit elements are formed. For example, the second interlayer insulating layer ID2 may be formed on the handle substrate 10H. Then, holes IDH2, which define areas in which the variable resistive layers Rw and the insertion layers 20 are to be formed, may be formed in the second interlayer insulating layer ID2. The variable resistive layer Rw and the insertion layer 20 may be filled in the holes IDH2 to form the second circuit elements. After the variable resistive layer Rw and the insertion layer 20 are filled in holes IDH2, a chemical mechanical polishing (CMP) process may be further performed to electrically isolate the second circuit elements.

Referring to FIG. 2c, the second portion stack ST2 of the handle substrate 10H is contacted with the first portion stack ST1 of the substrate 10 and bonded. For example, after a surface (Bb of FIG. 2b) of the second portion stack ST2 is contacted with a surface (Ba of FIG. 2a) of the first portion stack ST1 of the substrate 10, a bonding process may be performed between the first portion stack ST1 and the second portion stack ST2. The bonding process may be performed at a room temperature or through suitable heat treatment, according to a desired bonding method. For example, the heat treatment may be performed at a temperature of about 400° C. or less for several seconds to several hours using rapid thermal annealing or laser annealing, in order to achieve a desired silicidation reaction or eutectic alloy reaction.

The bonding of the first portion stack ST1 and the second portion stack ST2 may be performed at the insertion layer 20, located between the diode layer Da of the first portion stack ST1 and the variable resistive layer Rw of the second portion stack ST2. Accordingly, a first bonding layer BL1 may be formed between the diode Da and the insertion layer 20. For example, when the diode layer Da is a silicon-based semiconductor material and the insertion layer 20 includes a silicidable metal layer, the first bonding layer BL1 may include a metal silicide (MSiₓ) layer formed by a reaction between the insertion layer 20 and the diode layer Da. The metal silicide layer may be provided as a bonding layer. The metal silicide layer reduces resistance at a contact interface between the insertion layer 20 and the diode layer Da.

Although not shown, in an exemplary embodiment, another insertion layer including a bonding material layer may bealso formed on the diode layer Da of the first portion stack ST1. The bonding between the first portion stack ST1 and the second portion stack SR2 may be performed between the insertion layers. In this case, the first bonding layer BL1 may include an alloy layer, such as an eutectic alloy film. In an exemplary embodiment, the bonding between the first portion stack ST1 and the second portion stack ST2 may be obtained by Vander Waals force at a contact interface between the first interlayer insulating layer ID1 and the second interlayer insulating layer ID2. Alternatively, the first portion stack ST1 and the second portion stack ST2 may be bonded by a chemical reaction between the first interlayer insulating layer ID1 and the second interlayer insulating layer ID2. In the case of the bonding by the chemical reaction, a second bonding layer BL2 may be formed at the contact interface between the first interlayer insulating layer ID1 and the second interlayer insulating layer ID2. For example, when the bond between the first interlayer insulating layer ID1 and the second interlayer insulating layer ID2 includes a silicon-oxygen bond, the second bonding layer BL2 may include a reaction layer by formation of a siloxane network through polymerization of a silanol bond. In addition, the bonding of the first portion stack ST1 and the second portion stack ST2 may be obtained by a Vander Waals bond of the first interlayer insulating layer ID1 and the second interlayer insulating layer ID2.

The bonding process may be performed in a wafer-scale level or a chip-scale level. Preferably, in the bonding process, one of the first portion stack ST1 or the second portion stack ST2 may be bonded at the wafer-scale level, while the other of the first portion stack ST1 or the second portion stack ST2 may be bonded at the chip-scale level. As a result, thermal stress after the bonding process may be alleviated and an alignment process between the first circuit elements of the first portion stack ST1 and the second circuit element of the second portion stack ST2 may be more easily performed.

After the first portion stack ST1 and the second portion stack ST2 are bonded, the handle substrate 10H may be removed. In order to remove the handle substrate 10H, the handle substrate 10H may be separated from the separation layer SL as indicated by an arrow A. As a result, circuit elements, in which the first interconnection layer WL, the diode layer Da, and a variable resistor Rw are sequentially stacked on the substrate 10, may be obtained as in a circuit diagram shown in FIG. 1a. Next, a surface treatment process may be performed to remove any remaining separation layer SL. A process of forming an upper electrode of the variable resistor Rw or a second interconnection layer (for example, a bit line) on the second portion stack ST2 may be performed so that the array of the memory cells may be implemented.

Although not shown, in an exemplary embodiment, an upper structure on the variable resistor Rw, for example, the upper electrode and/or the second interconnection layer (see BL of FIG. 1a) may be formed before the variable resistive layer Rw is formed on the handle substrate 10H. That is, before the variable resistive layer Rw is formed on the handle substrate 10H, the second interconnection layer may be formed on the handle substrate 10H, and then the upper electrode may be formed on the second interconnection layer. In this case, the unit memory cell structure may be implemented through only the bonding process of the first portion stack ST1 and the second portion stack ST2.

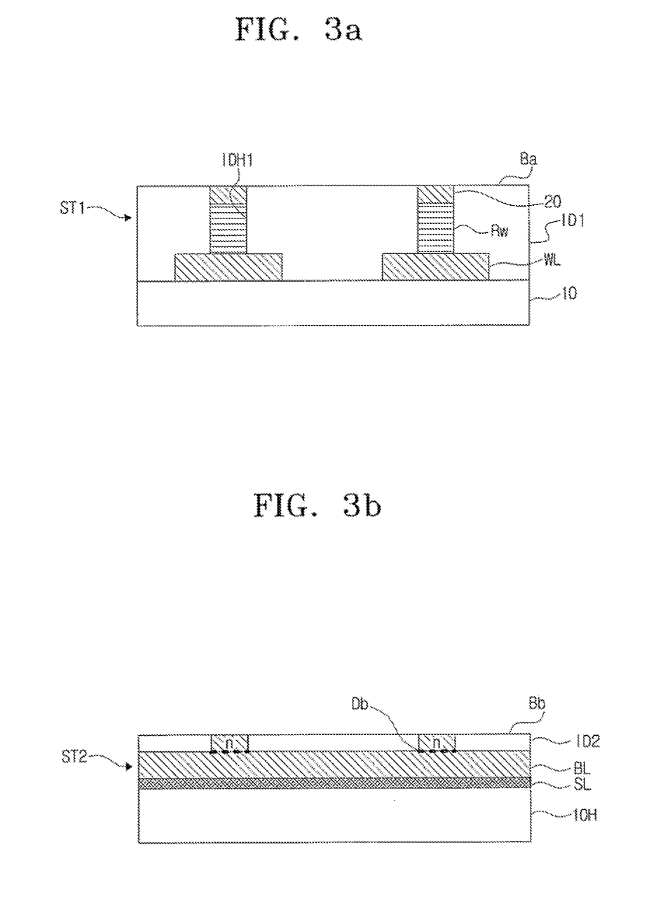

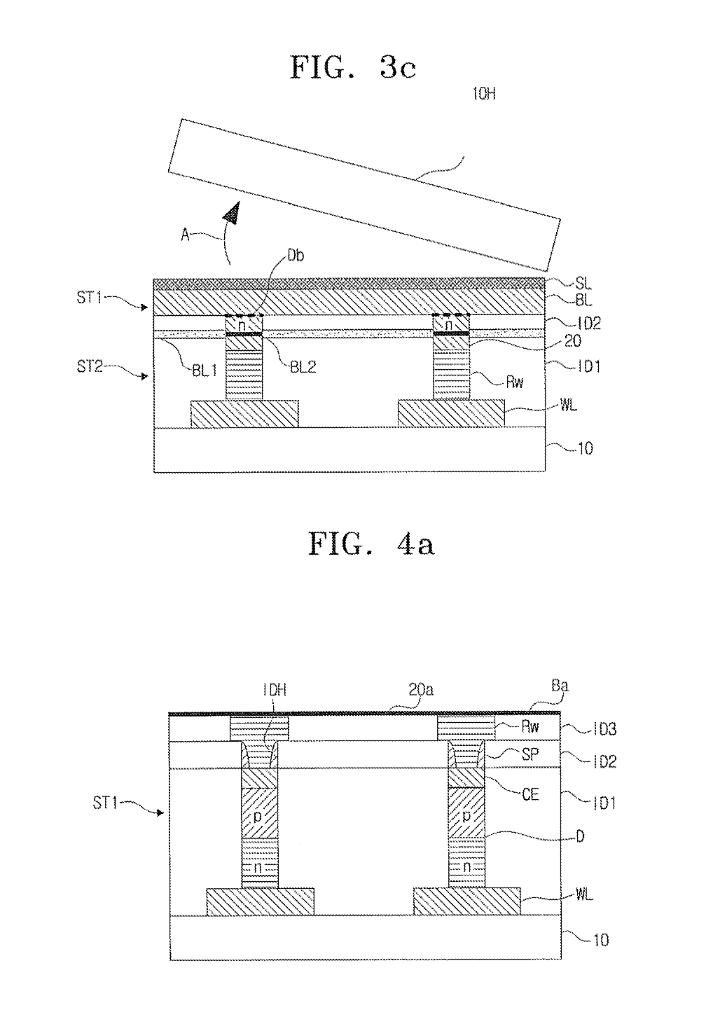

The memory cell structure including the diode Da, Db, or Dc and the variable resistor Rw may have a pillar structure. In consideration that a cell pitch may be reduced to 20 nm or less for high integration of the memory cell, the pillar structure may reach a height of 300 nm to 500 nm to have a high aspect ratio of above 10 or more than 20. In particular, in the case of the typical PN junction diode, since the height of the diode need to increase in order to enhance an ON current level, the aspect ratio of the pillar structure may further increase. In addition, for a diode such as a PIN diode to which a new semiconductor layer or impurity layer is added in terms of a functional advantage such as reduction in a parasitic current, the height of the diode may be increased, and accordingly, the aspect ratio of the pillar structure may be further increased. The forming the memory cell structure with a high-aspect through a continuous etching process is not easy due to leaning of the pillar structure caused during a fabrication process. However, according to the exemplary embodiment, the memory cell may be formed without the leaning issue by dividing the memory cell structure with the pillar structure of a high aspect ratio into each of portion stacks and bonding the portion stacks to each other so that an effect on reduction in a height is obtained for forming the device, and accordingly, the leaning during the fabrication process of the memory cell structure can be prevented. FIGS. 3a to 3c illustrate an exemplary method of manufacturing a non-volatile memory device having the unit memory cell shown in FIG. 1b. In FIGS. 3a to 3c, description of components having the same reference numerals as the components of FIGS. 2a to 2c may be with reference to the above-described disclosure unless not contradicted with each other, and will be omitted below.

The unit memory cell MCn2 of FIG. 1b has a unit memory cell structure in which a connection sequence of the diode Db and the variable resistor Rw is opposite to that of the diode Da and the variable resistor Rw of the unit memory cell MCn1 of FIG. 1a. Thus, referring to FIG. 3a, a first circuit element including a variable resistive layer Rw is formed on a substrate 10. For example, a first interlayer insulating layer ID1 may be formed on the substrate 10 on which a first interconnection layer WL is formed, Next, holes IDH1, for the variable resistive layer Rw, may be defined within the first interlayer insulating layer ID1. Subsequently, the variable resistive layer Rw may be formed in each of the holes IDH1. The variable resistive layer Rw may be formed by filling a material or the variable resistive layer Rw in the holes IHD1 and appropriately performing a CMP process.

Alternatively, before the first interlayer insulating layer ID1 is formed, a material layer for the variable resistive layer Rw may be formed on the substrate 10 and patterned to form the variable resistive layer Rw. Next, the first interlayer insulating layer ID1 may be formed to passivate the variable resistive layer Rw.

For example, the first interlayer insulating layer ID1 may include silicon oxide or silicon nitride formed by a HDP deposition method. The first interlayer insulating layer ID1 may include a layer that easily forms a molecular bonding layer, such as a reaction layer by network formation for a subsequent bonding process of portion stacks ST1 and ST2. The layer may include a metastable insulating layer such as a silicon oxide or a silicon nitride like layer.

An insertion layer 20 may be formed on the variable resistive layer Rw. The insertion layer 20 may include an intermediate electrode layer disposed between the variable resistive layer Rw and a diode layer (Db of FIG. 3b). Alternatively, the intermediate electrode layer may include an upper electrode layer of the variable resistive layer Rw, a diffusion barrier layer, or an omhic contact layer, or may perform the combined functions thereof.

The insertion layer 20 may include a bonding material layer for bonding the first portion stack ST1 and the second portion stack ST2 between the diode layer Db and the variable resistive layer Rw. The bonding material layer may include a conductive layer that is subject to metal alloying, via silicidation or a eutectic reaction. In addition, the bonding material layer may include a metastable metal having metal conductivity.

In the exemplary embodiment shown in FIG. 3a, the insertion layer 20 is formed in the first portion stack ST1. However, as described with reference to FIG. 2b, the insertion layer 20 may be formed in the second portion stack ST2 of a handle substrate 10H (which will be described later), or both in the first portion stack ST1 and the second portion stack. ST2.

The first portion stack ST1, which has the first circuit element that includes the first interconnection layer WL and the variable resistive layer Rw that are stacked perpendicular to a surface of the substrate 10 through the above-described processes, may be provided. Although not shown, it should be understood that the additional layer, such as a lower electrode layer, a barrier layer, an ohmic contact layer, or an impurity layer, may be further formed between the first interconnection layer WL and the variable resistive layer Rw.

Referring to FIG. 3b, the second portion stack ST2 includes a second circuit element to be delivered onto a surface Ba of the first portion stack ST1 of the substrate 10 and is formed on the handle substrate 10H. The handle substrate 10H may include a material similar to the substrate 10 or may be a dummy silicon wafer.

The second circuit element may include a Schottky barrier diode Db formed on a second interconnection layer BL. If the second interconnection layer BL is a metal interconnection pattern layer, then Schottky barrier diode Db, as shown in FIG. 3b, may be formed from an n-type semiconductor layer. For example, an n-type polysilicon layer may be formed on the second interconnection layer BL. Although not shown, if the second interconnection layer BL is a high concentration impurity layer, then the Schottky diode Db may formed on the second interconnection layer BL from a metal layer having a suitable work function. Alternatively, a p-type Schottky barrier diode or a combination of P-type and N-type Schottky diodes may be formed.

In an exemplary embodiment, a high concentration impurity region may be formed on a surface of the n-type semiconductor layer. An ohmic contact layer, with respect to the insertion layer 20 of the first circuit element, may be provided by the high concentration impurity region.

Referring to FIG. 3c, the second portion stack ST2 of the handle substrate 10H is contacted with the first portion stack ST1 of the substrate 10. Then, a surface Bb of the second portion stack ST2 is bonded with the surface Ba of the first portion stack ST1 of the substrate 10.

The bonding process may be performed in a wafer-scale level or a chip-scale level as described above. Alternatively, the bonding process may be performed on the first portion stack ST1 or the second portion stack ST2 at a wafer-scale level and on the other of first portion stack ST1 or the second portion stack ST2 on a chip-scale level. In this case, thermal stress after the bonding process may be alleviated and an alignment process between the first circuit element of the first: portion stack ST1 and the second circuit element of the second portion stack ST2 may be more easily performed.

The bonding of the first portion stack ST1 and the second portion stacks ST2 may be implemented in the insertion layer 20 between the semiconductor layer provided for the diode layer Db of the first portion stack ST1 and the variable resistive layer Rw of the second portion stack ST2. Therefore, a first bonding layer BL1 may be formed between the circuit elements Db and Rw. The first bonding layer BL1 may include a metal silicide layer (MSiₓ).

In an exemplary embodiment, a first insertion layer and a second insertion layer, both of which include a bonding material layer, may be formed on the variable resistive layer Rw of the first portion stack ST1 and the diode layer Db of the second portion stack ST2, respectively. The first insertion layer may include a different material from the second insertion layer and each of the first insertion layer and the second insertion layer may include a metal that is subject to a eutectic reaction, such as Au, Ag, Al, Cu, Si, Mo, Sn, Pb, Ga, Bi, In, Pb or Zn. In this case, the first bonding layer BL1 may include a eutectic alloy layer. In an exemplary embodiment, if the insertion layer 20 includes metastable metal having metal conductivity, the first bonding layer BL1 may include a suitable alloy layer from the metastable metal.

In an exemplary embodiment, the first portion stack ST1 and the second portion stack ST2 may be bonded by Vander Waals force at a contact interface between the first interlayer insulating layer ID1 and the second interlayer insulating layer ID2. Alternatively, the first portion stack ST1 and the second portion stack ST2 may be bonded by a chemical reaction between the first interlayer insulating layer ID1 and the second interlayer insulating layer ID2. In the case of the bonding by the chemical reaction, a second bonding layer BL2 may be formed at the contact interface. The second bonding layer BL2 may include a reaction layer by formation of a siloxane network through polymerization of a silanol bond.

When the first portion stack ST1 and the second portion stack ST2 are bonded by the first bonding layer BL1 or the second bonding layer BL2, the handle substrate 10H is removed. A body of the handle substrate 10H may be easily separated from a separation layer SL, as indicated by an arrow A. As a result sequentially stacked circuit elements, including the first interconnection layer WL, the variable resistor Rw, and the diode Db, may be obtained on the substrate 10 as in the circuit diagram of FIG. 1b.

To obtain a device in which the diode layer Db is disposed on the variable resistive layer Rw, like the non-volatile memory device shown in FIG. 3c, the diode layer and the variable resistive layer are formed through separate processes, and thus a thermal burden for forming the diode layer is independent of a process of forming the variable resistive layer. As a result, when compared with a conventional non-volatile memory device, a film quality of the diode layer and the variable resistive layer may be improved independently. In addition, when compared with a conventional non-volatile memory device, since the Schottky barrier diode Db does not need a junction structure between semiconductors having different conductivities, a configuration of a cell array and a fabrication process may be simplified.

Although FIGS. 3a to 3c illustrate the Schottky barrier diode, it should be understood by a person with ordinary skill in the art that the PN diode (see Da of FIG. 1a) or the Zener diode (see Dc of FIG. 1c) can be used to obtain an advantage like the Schottky barrier diode. For example, non-volatile memory device may be provided by contacting a second portion stack ST2, including a PN diode layer or a Zener diode layer formed on a handle substrate 10H, with a first portion stack ST1, including the variable resistive layer Rw, formed on a substrate 10.

In the above-described exemplary embodiments, the diode layer may be modified with respect to a material, junction structure, and height to enhance driving characteristics and to ensure large capacity. According to the exemplary embodiments, since the diode layer and the variable resistive layer are completed through separate processes, a reliable non-volatile memory device may be provided without thermal damage of the variable resistive layer due to formation of the diode layer.

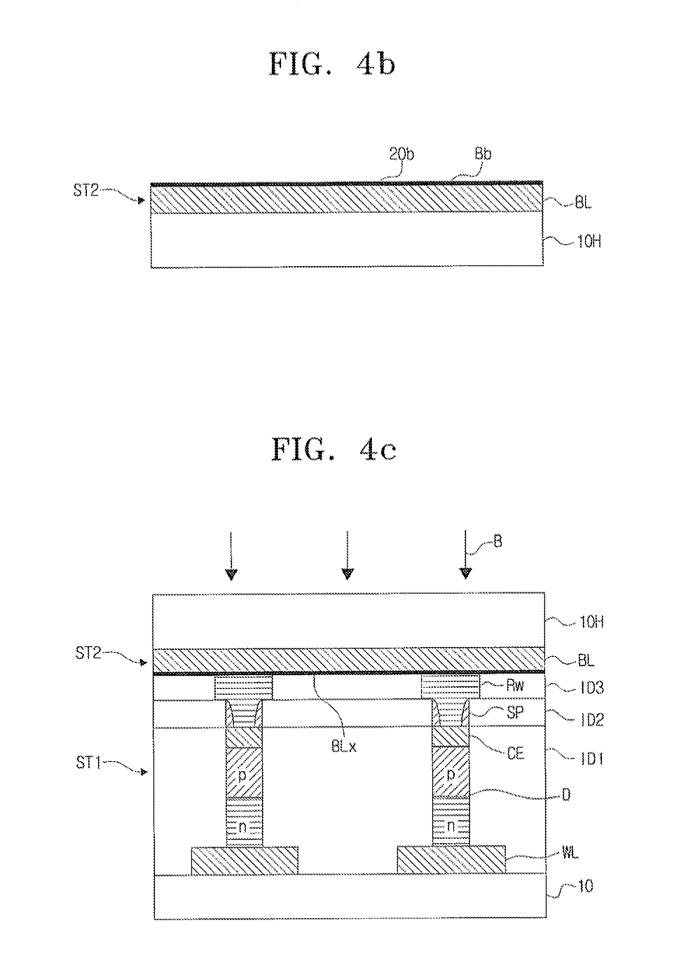

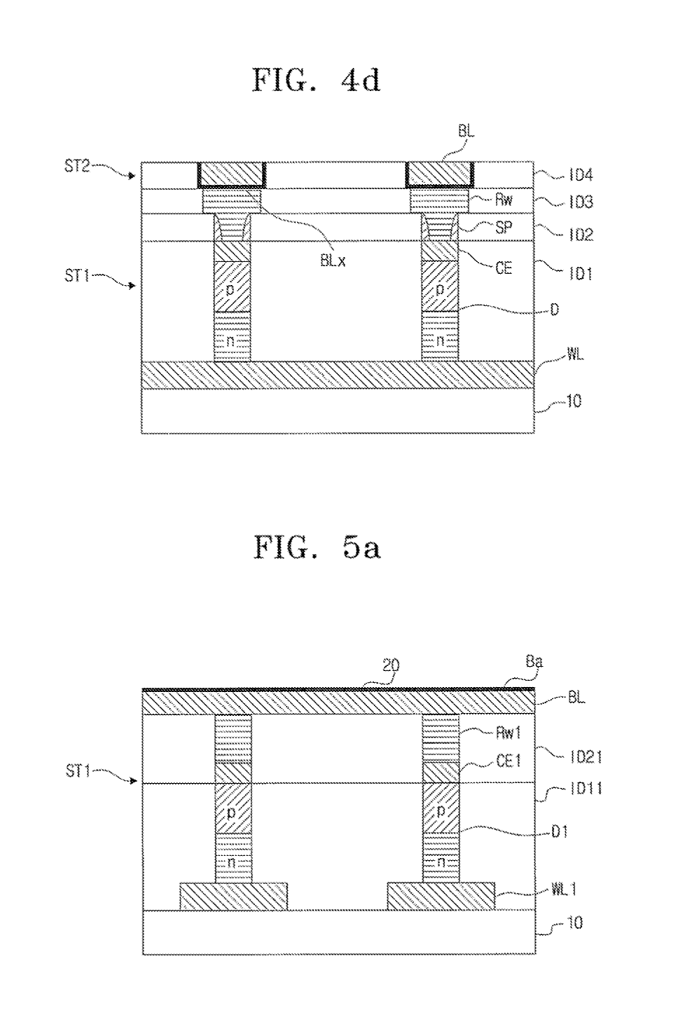

FIGS. 4a to 4d illustrate an exemplary method of manufacturing a non-volatile memory device. In FIGS. 4a to 4d, description of components having the same reference numerals as the components of FIGS. 2a to 3c may be with reference to the above-described disclosure unless not contradicted with each other and will be omitted below.

Referring to FIG. 4a, a first circuit element, including a first interconnection layer WL, a diode layer D, and a variable resistive layer connected to the diode layer D in series, may be formed on a substrate 10.

In an exemplary embodiment, the variable resistive layer Rw may be restricted to reduce a contact area with an intermediate electrode layer CE. The reduction in the connect area may reduce a programming current of a variable resistive layer Rw. If the variable resistive layer Rw includes a phase-change material, a spacer SP restricts the variable resistive layer Rw, thereby reducing a contact area between the phase-change material and a lower electrode to enhance an effective current density for programming the variable resistive layer Rw, so that driver circuits can be smaller. Thus, a device integration density may be further improved.

The spacer SP may be formed by forming suitable holes IDH exposing the intermediate electrode layer CE, which is formed in a second interlayer insulating layer ID2 depositing a suitable spacer material layer in the holes IDH, and performing an etch back process on the spacer material layer. The spacer SP may include an electrical or thermal insulator. The variable resistive layer Rw may extend onto the second interlayer insulating layer ID2. A third interlayer insulating layer ID3 may be additionally formed to insulate the variable resistive layer Rw.

In the exemplary embodiment shown in FIG. 4a, a first insertion layer 20a may be provided on the variable resistive layer Rw or the third interlayer insulating layer ID3. For example, the first insertion layer 20a passes over an upper surface of the variable resistive layer Rw and extends onto the third interlayer insulating layer ID3 like a second interconnection layer (BL of FIG. 4b) which will be described layer. As described above, the first insertion layer 20a may include an intermediate electrode layer, a diffusion barrier layer, an ohmic contact layer, or a bonding material layer or have a multi-layered stacking structure including at least two or more layers from among the layers. In another exemplary embodiment, the insertion layer 20a may be locally formed only on the variable resistive layer Rw as described above.

Referring to FIG. 4b, the second interconnection layer BL is formed on a handle substrate 10H. The second interconnection layer BL may have a line pattern crossing the first interconnection layer WL of the substrate 10. In some exemplary embodiments, the second interconnection BL may be formed by a damascene process or a dual damascene process. In this case, the second interconnection layer BL may include a noble metal that is difficult to be etched, for example, Pt, Ir, or Ru. In some embodiments, the second interconnection layer BL may include Cu or a Cu alloy to provide a low resistance interconnection layer. In this case, the second interconnection layer BL may be formed on the handle substrate 10H through a damascene process or a dual damascene process.

In general, since Cu atoms in a Cu-based interconnection layer are easy to be diffused into the interlayer insulating layers, it is necessary to form a diffusion barrier layer to surround a Cu interconnection or to be interposed between the Cu interconnection and the interlayer insulating layer (see BLx of FIG. 4d). The diffusion barrier layer may include Ta, TaN, TIN, Ti, TiW, W, WN, TIN, TiSiN, WSiN, TaSiN, SiN, or any combination thereof. Thus, a second insertion layer 20b including a Cu diffusion barrier layer, may be formed on the second interconnection layer BL.

To form the insertion layer surrounding the second interconnection layer BL, an interlayer insulating layer, which serves as a mold for a damascene process of a metal interconnection layer, may be formed on the handle substrate 10H. A trench, in which a metal interconnection layer is to be filled, is formed on the interlayer insulating layer. Next, a metal layer is filled in the trench, and then a planarization process is performed on the metal layer to form the second metal interconnection layer BL. Subsequently, the interlayer insulating layer is removed and the insertion layer may be formed on an entire surface of the exposed metal interconnection layer including a side thereof. In this case, the insertion layer may include stacked metal layers, such as diffusion barrier layer and a bonding material layer. Next, a new interlayer insulating layer (see ID4 of FIG. 4d) is formed between the metal interconnection layers BL including the insertion layer to implement the second portion stack ST2.

Referring to FIG. 4c, the second portion stack ST2 is contacted with the first portion stack ST1. Thus, the first portion stack ST1 may be bonded to the second portion stack ST2.

The bonding process may be performed on a wafer-scale level or on a chip-scale level. Alternatively, the bonding process may be performed on the first portion stack ST1 or the second portion stack ST2 on a wafer-level scale and on the other of the first portion stack. ST1 or the second portion stack ST2 on a chip-scale level.

When the first insertion layer 20a, of the first portion stack ST1, and the second insertion layer 20b, of the second portion stack ST2, include bonding material layers, the bonding of the first portion stack ST1 and the second portion stack ST2 may occur between the first insertion layer 20a and the second insertion layer 20b. Thus, a bonding layer BLx may be formed between the first insertion layer 20a and the second insertion layer 20b. In this case, the bonding layer BLx may include a reaction layer, such as a eutectic ahoy layer. The bonding layer BLx may be formed through a low temperature bonding process of about 400° C. or less.

In addition, although now shown, another bonding layer may be formed between the third interlayer insulating layer ID3 and an uppermost interlayer insulating layer (for example, see ID4 of FIG. 4d). When the interlayer insulating layers include a silicon-oxygen bond, the other bonding layer may include a reaction layer having a siloxane network through polymerization of a silanol bond. In an exemplary embodiment, the interlayer insulating layers may also be bonded through a Vander Waals bond.

When the first portion stack ST1 and the second portion stack ST2 are bonded, the handle substrate 10H is removed. In the exemplary embodiment shown in FIG. 4c, the handle substrate 10H may be removed by a planarization process, a CMP process, or an etch back process, which may be performed to a desired depth, in a direction of an illustrated arrow B.

FIG. 4d illustrates an exemplary memory cell array of a non-volatile memory device. As described above, the second interconnection layer BL may include a low resistance interconnection layer, such as a noble metal-based material or copper, or an alloy thereof. The low resistance interconnection layer may be formed by a suitable patterning process or a damascene or a dual damascene process. As shown in FIG. 4d, the second interconnection layer BL may be surrounded by a diffusion barrier layer (insertion layer) to be isolated from other components. When the second interconnection layer BL includes a low resistance interconnection layer, a bit line configuration directly connected to the variable resistive layer Rw may be obtained without an intermediate electrode layer.

According to the above-described exemplary embodiments, it is possible to reliably form an interconnection layer that causes a reaction with an adjacent layer during a process or an interconnection layer that uses a material difficult to be etched. It is also possible to use these interconnection layers as an upper electrode for the variable resistive layer so that the high-speed non-volatile memory device may be implemented due to a low resistance interconnection structure.

The features disclosed with reference to FIGS. 2a to 4d are compatible with each other and thus may be substituted or combined, unless such substitution or combination is contradictory. It should be understood that modified embodiments also belongs to the scope of the present invention. For example, the variable resistive layer Rw, as shown in FIG. 2b, may be modified to be as shown in FIG. 4a. In addition, a bit line may be formed the structure shown in FIG. 2c, using the process for forming the second interconnection layer BL, as shown in FIGS. 4b to 4d.

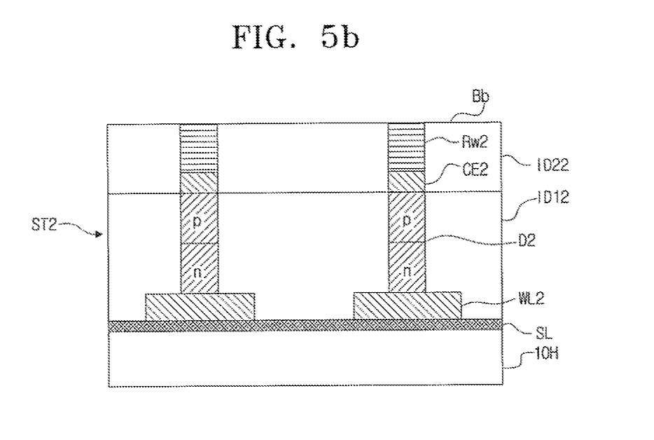

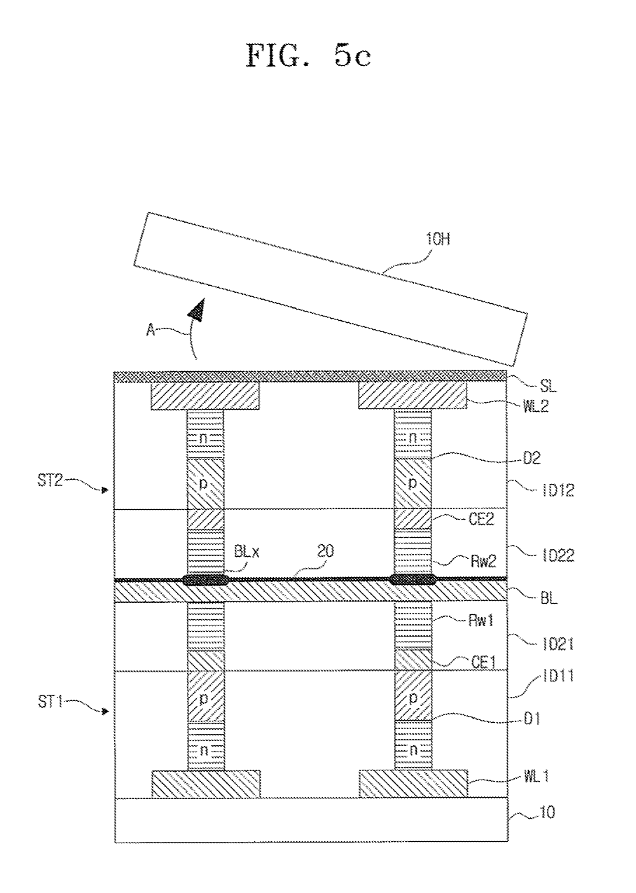

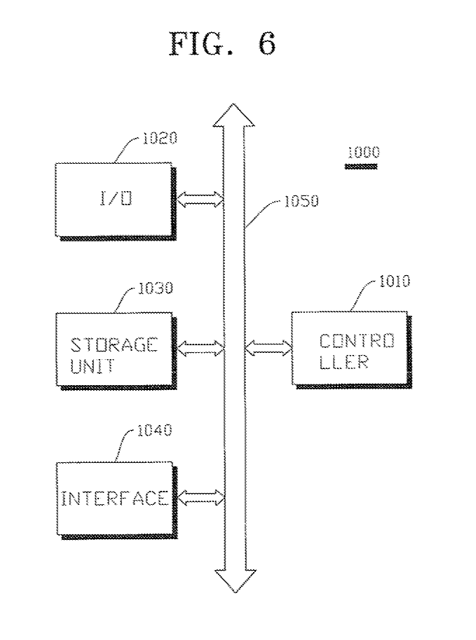

FIGS. 5a to 5c illustrate an exemplary method of manufacturing a non-volatile memory device. In FIGS. 5a to 5c, description of components having the same reference numerals as the components of FIGS. 2a to 4d may be with reference to the above-described disclosure unless not contradicted with each other, and will be omitted below.

Referring to FIG. 5a, a first portion stack ST1, including a first circuit element having a first interconnection layer WL, a diode layer D1, an intermediate electrode layer CE1, a variable resistive layer Rw1, and a second interconnection layer BL, may be formed on a substrate 10. Interlayer insulating layers ID11 and ID21, which passivate the first circuit element, may be formed in the first portion stack ST1. Therefore, a plurality of first memory cells may be formed in the first portion stack ST1. The respective circuit elements within the first portion stack ST1 may be fabricated by separately forming the respective circuit elements at each level based on the method disclosed in FIG. 2a through FIG. 4d.

In an exemplary embodiment, an insertion layer 20 may be formed on an upper surface Ba of the first portion stack ST1. The insertion layer 20 may include the above-described intermediate electrode layer, the diffusion barrier layer, the ohmic contact layer, the bonding material layer, or a multi-layered structure including a stack of at least two or more of the above-described layers. In addition, although not shown, the insertion layer 20 may have a same pattern as the second interconnection layer BL and may be formed to overlap the second interconnection layer BL or to surround the second interconnection layer BL. Alternatively, the insertion layer 20 may be formed on a portion of an interlayer insulating in which the second interconnection layer BL is not formed.

Referring to FIG. 5b, a second portion stack ST2, including a second circuit element, may be formed on a handle substrate 10H. The second circuit element may include a first interconnection layer WL2, a diode layer D2, an intermediate electrode layer CE2, and a variable resistive layer Rw2. In addition, interlayer insulating layers ID12 and ID22, which passivate the second circuit elements, may be further formed in the second portion stack ST2. Therefore, a plurality of second memory cells are formed in the second portion stack ST2. Although not shown, an insertion layer may be further formed on a surface Bb of the second portion stack ST2.

Referring to FIG. 5c, the second portion stack ST2 of the handle substrate 10 is contacted with the first portion stack ST1 of the substrate 10, so that the surface Bb of the second portion stack ST2 may overlap the surface Ba of the first portion stack ST1. The second portion stack ST2 may then be bonded with the first portion stack ST1. The bonding process may be performed on a wafer-scale level or a chip-scale level, as described above. The first portion stack ST1 and the second portion stack ST2 may be bonded at the insertion layer 20 between the second interconnection layer BL of the first portion stack ST1 and the variable resistive layer RW2 of the second portion stack ST2. The first bonding layer BLx may include a metal silicide layer (MSix) or a eutectic alloy layer, as described above. In an exemplary embodiment, the insertion layer 20 may include a metastable metal having metal conductivity. In this case, the insertion layer 20 may include an alloy layer suitable for the first bonding layer BLx.

In an exemplary embodiment (not shown), the first portion stack ST1 and the second portion stack ST2 may be bonded by Vander Waals' force at a contact interface between the interlayer insulating layers ID21 and ID22 of the first and second portion stacks ST1 and ST2. Alternatively, the first portion stack ST1 and the second portion stack ST2 may be bonded by a chemical reaction between the interlayer insulating layer ID21 and ID22. A bonding layer (not shown) may be formed at the contact interface.

When the first portion stack ST1 and the second portion stack ST2 are bonded by the bonding layers, the handle substrate 10H is removed. As indicated by an arrow A, a body of the handle substrate 10H may easily be separated from a separation layer SL. As a result, a three-dimensional non-volatile memory device in which a plurality of unit memory cells in each layer are vertically stacked may be obtained. The three dimensional non-volatile memory device may share the second interconnection layer BL, for example, a bit line.

According to the exemplary embodiments, a plurality of first memory cells and a plurality of second memory cells are formed by stacking an upper stack and a lower stack, so that a three dimensional non-volatile memory having a multi-level cell configuration may be provided. In addition, when the exemplary non-volatile memory device is manufactured, the formation of the diode, in one stack portion, does not damage thermally the circuit elements in another stack portion.

In addition, even when an aspect ratio of the unit memory cell including a vertical diode is large, the exemplary non-volatile memory device provides a high degree of integration, with reliability, in spite of the large aspect ratio. In the exemplary embodiments, a PN diode has been illustrated as a diode, but the PN diode is merely illustrative and as described above, other diodes such as a Schottky barrier diode or a Zener diode may be used.

An exemplary non-volatile memory device, disclosed herein, may be implemented in a single memory device or in a system on chip (SOC)-type memory device, together with heterogeneous devices, such as a logic processor, an image sensor, or a radio frequency (RF) device on one wafer chip. An exemplary non-volatile memory device may be implemented by bonding a wafer chip, in which the non-volatile memory device is formed, to another wafer chip, in which the heterogeneous device is formed, using an adhesive, soldering, or wafer bonding technology.

In addition, an exemplary non-volatile memory device may be implemented with various types of semiconductor packages. For example, an exemplary non-volatile memory device may be packaged in a package on package (PoP), a ball grid array (BGA), a chip scale package (CSP), a plastic leaded chip carrier (PLCC), a plastic dual in-line packages (PDIP) a die in waffle pack, a die in wafer FoSM, chip on board (COB), a ceramic dual in-line package (CERDIP), a plastic metric quad flat pack (MQFP), a thin quad flatpack (TQFP), a small outline (SOIL), a shrink small outline package (SSOP), a thin small outline (TSOP), a thin quad flatpack (TQFP), a system in package (SIP), a multi-chip package (MCP), a wafer-level fabricated package (WFP), or a wafer-level processed stack package (WSP). A package mounted with an exemplary non-volatile memory device may further include controllers or logic devices configured to control an exemplary non-volatile memory device.

FIG. 6 is a block diagram illustrating an electronic system 1000 including a non-volatile memory device according to an exemplary embodiment of the present invention.

Referring to FIG. 6, the electronic system 1000 according to an exemplary embodiment may include a controller 1010, an input/output (I/O) device 1020, a storage device 1030, an interface 1040, or a bus 1050. The controller 1100, the I/O device 1020, the storage device 1030, or the interface 1040 may be connected with each other through the bus 1050.

The controller 1010 may include at least one of a microprocessor (MP), a digital signal processor, a microcontroller, or logic devices performing functions similar thereto. The input/output unit 1020 may include a keypad, a keyboard, or a display device. The storage device 1030 may store data or commands. The storage device 1030 may include the three-dimensional non-volatile memory device herein.

In an exemplary embodiment, the storage device 1030 may have a heterogeneous structure further including another type of a semiconductor memory device (for example, a dynamic random access memory (DRAM), a static random access memory (SRAM), or the like). The interface 1040 may transmit data to a communication network or receive data from the communication network. The interface 1040 may be of a wired or wireless type, and thus the interface 1040 may include an antenna or a wired or wireless transceiver. Although not shown, the electronic system 1000 may further include a high-speed DRAM and/or SRAM as an operational memory that improves an operation of the controller 1010.

The electronic system 1000 may be applied to a personal digital assistant (PDA), a portable computer, a tablet personal computer (PC), a wireless phone, a mobile phone, a digital music player, a memory card, or any electronic product capable of transmitting or receiving information in a wireless environment.

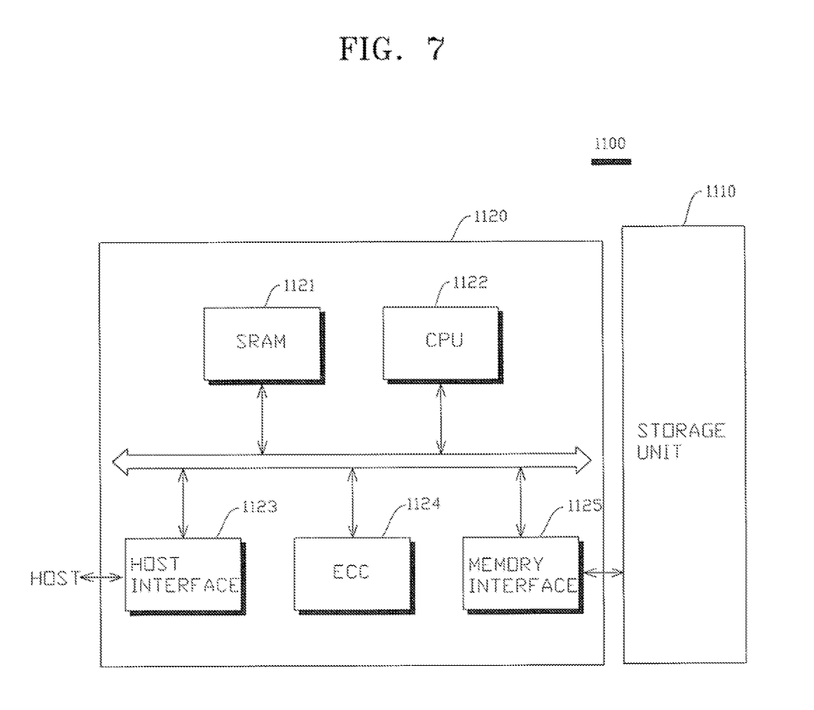

FIG. 7 illustrates an exemplary memory card 1100 including an exemplary non-volatile memory device.

Referring to FIG. 7, an exemplary memory card 1100 includes a storage unit 1110. The storage unit 1110 includes an exemplary non-volatile memory device. The storage device 1110 may further include another type of a semiconductor memory device (for example, a DRAM, a SRAM, and the like). The memory card 1100 may further include a memory controller 1120 that controls data exchange between a host and the storage device 1110.

The memory controller 1120 may include a central processing unit (CPU) 1122 that controls an overall operation of the memory card 1100. The memory controller 1120 may include a SRAM 1121 used as an operational memory of the CPU 1122. Further, the memory controller 1120 may further include a host interface 1123 and a memory interface 1125. The host interface 1123 may include a protocol for data exchange between the memory card 1100 and the host. The memory interface 1125 may connect the memory controller 1120 and the storage device 1110. Further, the memory controller 1120 may further include an error correction block (ECC) 1124. The error correction block 1124 may detect and correct an error of data read from the storage device 1110. Although not shown, the memory card 1100 may further include a ROM device which stores code data for interfacing with the host. The memory card 1100 may be used as a portable data storage card. The memory card 1100 may include an exemplary non-volatile memory device and may be implemented with a solid state drive (SDD) which may replace a hard disc of a computer system. Thus an exemplary non-volatile memory device may provide petascale computing performance.

While certain exemplary embodiments have been described above, it will be understood that the embodiments described are by way of example only. Accordingly, the devices and methods described herein should not be limited based on the described exemplary embodiments. Rather, the systems and methods described herein should only be limited in light of the claims that follow when taken in conjunction with the above description and accompanying drawings.

What is claimed is:

1. A method of manufacturing a memory cell including at least one diode layer, at least one variable resistive layer and at least one interconnection layer, where the at least one diode layer and the at least one variable resistive layer are coupled with each other and arranged perpendicular to a surface of a substrate, and where the at least one interconnection layer is electrically connected with one end of the coupled at least one diode layer and at least one variable resistive layer, the method comprising:
forming, on the substrate, a first portion stack having a first circuit element including at least one layer selected from the at least one diode layer, the at least one variable resistive layer, and the interconnection layer;
forming, on a handle substrate, a second portion stack having a second circuit element including at least the other layer selected from the at least diode layer, the at least variable resistive layer, and the at least interconnection layer;
joining the second portion stack on the handle substrate with the first portion stack on the substrate to electrically connect the first circuit element and the second circuit element; and
removing the handle substrate from the second portion stack.

2. The method of claim 1, where joining the second portion stack with the first portion stack comprises:
forming a first bonding layer between the first circuit element and the second circuit element.

3. The method of claim 2 where the first bonding layer comprises a metal silicide layer, a eutectic alloy layer or a combination thereof.

4. The method of claim 1, further comprising:
forming a first interlayer insulating layer over the first circuit element and a second interlayer insulating layer over the second circuit element, and
where joining the second portion stack with the first portion stack further comprises:
forming a second bonding layer between the first interlayer insulating layer and the second interlayer insulating layer.

5. The method of claim 4, where the second bonding layer comprises a reaction layer formed by a siloxane network, a Vander Waals bonding layer or a combination thereof.

6. The method of claim 1, further comprising:
forming an insertion layer partially or entirely on at least one of an upper surface of the first portion stack and an upper surface of the second portion stack.

7. The method of claim 6, where the insertion layer comprises an intermediate electrode layer, a diffusion barrier layer, an ohmic contact layer, a bonding material layer, or a stacking structure including at least two or more of the intermediate electrode layer, the diffusion barrier layer, the ohmic contact layer, or the bonding material layer.

8. The method of claim 6, where the at least one diode layer comprises a silicon-based semiconductor material and the insertion layer includes a silicidable metal material.

9. The method of claim 1, where the diode layer and the at least one variable resistive layer are arranged to have a pillar-shaped structure.

10. The method of claim 1, where the at least variable resistive layer comprises a phase-change material, a variable resistive material, or a programmable metallization cell (PMC) material.

11. The method of claim 1, where the at least diode layer comprises a PN junction diode, a p-type semiconductor-intrinsic semiconductor-n-type semiconductor (PIN) diode, a Schottky barrier diode, or a Zener diode.

12. The method of claim 1, where the at least interconnection layer is formed by a damascene process or a dual damascene process.

13. The method of claim 12, where the at least interconnection layer comprises a noble metal, a noble metal alloy, copper, or a copper alloy.

14. The method of claim 12, further comprising:
forming a diffusion barrier layer on the at least interconnection layer.

15. The method of claim 1, further comprising:
forming a first memory cell in the first portion stack, the memory cell including a first diode layer, a first variable resistive layer, and a first interconnection layer;
forming a second memory cell in the second portion stack, the second memory cell including a second diode layer, a second variable resistive layer, and a second interconnection layer, and
where the first interconnection layer or the second interconnection layer is a common interconnection layer for both the first memory cell and the second memory cell.

16. A method of manufacturing a non-volatile memory device, the method comprising:
forming perpendicular to a surface of a substrate, a first portion stack including a plurality of first memory cells, where each first memory cell of the plurality of first memory cells includes a first diode layer, a first variable resistive layer, and a first interconnection layer;
forming, perpendicular to a surface of a handle substrate, a second portion stack including a plurality of second memory cells, where each second memory cell, of the plurality of second memory cells, includes a second diode layer, a second variable resistive layer, and a second interconnection layer;
bonding the second portion stack with the first stack portion; and
removing the handle substrate from the second portion stack.

17. The method of claim 16, where the first interconnection layer or the second interconnection layer is a common interconnection layer for both the plurality of first memory cells and the plurality of second memory cells.

18. A memory device comprising a plurality of memory cells, where each memory cell, of the plurality of memory cells, includes at least one diode layer, at least one variable resistive layer and at least one interconnection layer, where the at least one diode layer and the at least one variable resistive layer are coupled with each other and arranged perpendicular to a surface of a substrate, and where the at least one interconnection layer is electrically connected with one end of the coupled at least one diode layer and at least one variable resistive layer, the memory device comprising;
a first portion stack having a first circuit element including at least one layer selected from the at least one diode layer, the at least one variable resistive layer, and the interconnection layer;
a second portion stack having a second circuit element including at least the other layer selected from the diode layers, the variable resistive layers, and the interconnection layer; and
a bonding layer formed between the first portion stack and the second portion stack.

19. The memory device of claim 18, where the at least one diode layer comprises a PN junction diode, a p-type semiconductor-intrinsic semiconductor-n-type semiconductor (PIN diode, a Schottky barrier diode, or a Zener diode.

20. The memory device of claim where the at least variable resistive layer comprises a phase-change material, a variable resistive material, or a programmable metallization cell (PMC) material.
